(19) United States
(12) Patent Application Publication
(10) Pub. No.: US 2025/0280641 A1
(43) Pub. Date: Sep. 4, 2025

(54) TRANSPARENT DISPLAY DEVICE

(71) Applicant: LG Display Co., Ltd., Seoul (KR)

(72) Inventors: JaeHee Park, Paju-si (KR); DongYoon Kim, Paju-si (KR)

(73) Assignee: LG Display Co., Ltd., Seoul (KR)

(21) Appl. No.: 18/988,503

(22) Filed: Dec. 19, 2024

(30) Foreign Application Priority Data
Feb. 29, 2024 (KR) 10-2024-0030120

(51) Int. Cl. H10H 29/49; H10H 29/32; H10K 59/121; H10K 59/131

(52) U.S. Cl. CPC H10H 29/49; H10H 29/32; H10K 59/1213; H10K 59/1216; H10K 59/131

(57) ABSTRACT

A transparent display device is provided, which comprises a display area in which a plurality of subpixels are disposed to display an image, a plurality of transmissive areas disposed within the display area and transmitting external light, a first non-transmissive area disposed between the transmissive areas disposed to be adjacent to each other in a first direction and not transmitting external light, a second non-transmissive area disposed between the transmissive areas disposed to be adjacent to each other in a second direction and not transmitting external light, a first circuit portion disposed in the first non-transmissive area to drive the subpixel disposed in the first non-transmissive area, and a second circuit portion disposed in the second non-transmissive area to drive the subpixel disposed in the second non-transmissive area.

### CROSS-REFERENCE TO RELATED APPLICATIONS

This application claims priority to Korean Patent Application No. 10-2024-0030120, filed in the Republic of Korea on Feb. 29, 2024, the entire contents of which is hereby expressly incorporated by reference into the present application.

### BACKGROUND

### Field of the Invention

The present disclosure relates to a display device, and more particularly, a transparent display device.

### Description of the Related Art

Recently, studies for a transparent display device in which a user can view objects or images positioned at an opposite side of the display device are actively ongoing.

The transparent display device includes a display area on which an image is displayed, and a non-display area. The display area can include a transmissive area capable of transmitting external light and a non-transmissive area. The transparent display device can have high light transmittance in the display area through the transmissive area.

The description provided in the background section should not be assumed to be prior art merely because it is mentioned in or associated with the background section. The background section can include information that describes one or more aspects of the subject technology.

### SUMMARY OF THE DISCLOSURE

The transparent display device can improve transparency by increasing the transmissive area. However, when the transmissive area is increased, the non-transmissive area is reduced, and a problem occurs in that a plurality of signal lines and a plurality of circuit elements should be disposed in a non-transmissive area of a narrow area.

The present disclosure has been made in view of the above problems and it is an object of the present disclosure to provide a transparent display device that can improve transparency.

It is another object of the present disclosure to provide a transparent display device that can implement environment/social/governance (ESG) by attenuating occurrence of greenhouse gas that can occur due to a manufacturing process.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a transparent display device comprising a display area in which a plurality of subpixels are disposed to display an image; a plurality of transmissive areas disposed within the display area, transmitting external light; a first non-transmissive area disposed between the transmissive areas disposed to be adjacent to each other in a first direction, not transmitting external light; a second non-transmissive area disposed between the transmissive areas disposed to be adjacent to each other in a second direction, not transmitting external light; a first circuit portion disposed in the first non-transmissive area to drive the subpixel disposed in the first non-transmissive area; and a second circuit portion disposed in the second non-transmissive area to drive the subpixel disposed in the second non-transmissive area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings, in which:

FIG. 1 is a schematic perspective view illustrating a transparent display device according to one exemplary embodiment of the present disclosure;

FIG. 2 is a schematic plan view illustrating a transparent display panel according to one exemplary embodiment of the present disclosure;

FIG. 3 is a schematic view illustrating one exemplary embodiment of a pixel provided in an area A of FIG. 2;

FIG. 4 is a circuit view illustrating an example of a pixel element of a subpixel shown in FIG. 3;

FIG. 5 is a schematic view illustrating an example in which a plurality of signal lines and circuit elements are disposed;

FIG. 6 is a cross-sectional view illustrating an example of an area along line I-I′ of FIG. 5;

FIG. 7 is a view illustrating a crosstalk defect;

FIG. 8 is a view illustrating an example of a switching connection line and a sensing connection line;

FIG. 9 is a cross-sectional view illustrating an example of an area along line II-II′ of FIG. 8; and

FIG. 10 is a cross-sectional view illustrating an example of an area along line III-III′ of FIG. 8.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete and will fully convey the scope of the present disclosure to those skilled in the art.

A shape (e.g., sizes, lengths, widths, heights, thicknesses, locations, radii, diameters, and areas), a ratio, an angle and a number disclosed in the drawings for describing embodiments of the present disclosure are merely an example and thus, the present disclosure is not limited to the shown details. Like reference numerals refer to like elements throughout the disclosure. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion can be added unless ‘only˜’ is used. The terms of a singular form can include plural forms unless referred to the contrary.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “can.”

The term “or” means “inclusive or” rather than “exclusive or.” That is, unless otherwise stated or clear from the context, the expression that “x uses a or b” means any one of natural inclusive permutations. For example, “a or b” can mean “a,” “b,” or “a and b.” For example, “a, b or c” can mean “a,” “b,” “c,” “a and b,” “b and c,” “a and c,” or “a, b and c.”

In construing an element, the element is construed as including an error band although there is no explicit description. Any implementation described herein as an “example” is not necessarily to be construed as preferred or advantageous over other implementations.

In describing a position relationship, for example, when the position relationship is described as ‘upon˜’, ‘above˜’, ‘below˜’ and ‘next to˜’, one or more portions can be disposed between two other portions unless ‘just’ or ‘direct’ is used.

The terms, such as “below,” “lower,” “above,” “upper” and the like, can be used herein to describe a relationship between element(s) as illustrated in the drawings. It will be understood that the terms are spatially relative and based on the orientation depicted in the drawings.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” “A,” “B,” “(a),” and “(b),” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each element of the first, second and third elements. Further, the term “can” fully encompasses all the meanings and coverages of the term “can.”

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, a preferred embodiment of a transparent display device according to the present disclosure will be described in detail with reference to the accompanying drawings. Wherever possible, the same reference numbers will be used throughout the drawings to refer to the same or like parts. Also, in the following description, when the detailed description of the relevant known art is determined to unnecessarily obscure the subject matter of the present disclosure, the detailed description will be omitted.

Hereinafter, the exemplary embodiment of the present disclosure will be described in detail with reference to the accompanying drawings. All the components of each display device according to all embodiments of the present disclosure are operatively coupled and configured.

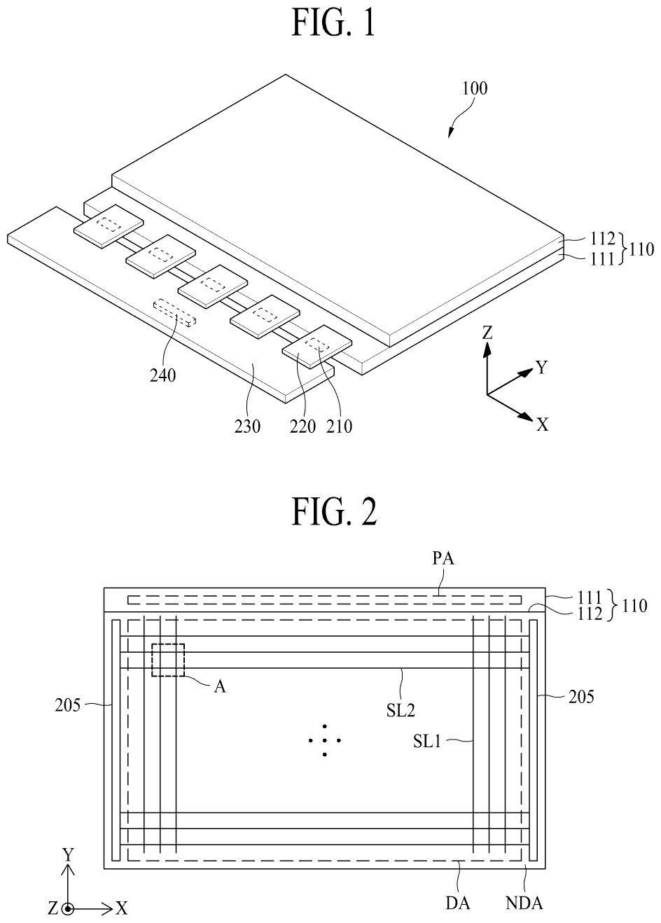

FIG. 1 is a schematic perspective view illustrating a transparent display device according to one exemplary embodiment of the present disclosure. FIG. 2 is a schematic plan view illustrating a transparent display panel according to one exemplary embodiment of the present disclosure.

Hereinafter, an X-axis represents a direction parallel with a gate line, a Y-axis represents a direction parallel with a data line, and a Z-axis represents a height direction of a transparent display device 100.

Although the transparent display device 100 according to one exemplary embodiment of the present disclosure will be described to be implemented as an organic light emitting display (OLED), it can be also implemented as a liquid crystal display (LCD), a plasma display panel (PDP), a quantum dot light emitting display (QLED), a light emitting display LED, a micro-LED display, or an electrophoresis display, etc.

Referring to FIGS. 1 and 2, the transparent display device 100 according to one exemplary embodiment of the present disclosure can include a transparent display panel 110, a source drive integrated circuit (hereinafter, referred to as “IC”) 210, a flexible film 220, a circuit board 230, and a timing controller 240.

The transparent display panel 110 includes a first substrate 111 and a second substrate 112, which face each other. The second substrate 112 can be an encapsulation substrate. The first substrate 111 can be a plastic film, a glass substrate or a silicon wafer substrate formed using a semiconductor process, without being limited thereto. As an example, the first substrate 111 can be a rigid substrate or a flexible substrate. The second substrate 112 can be a plastic film, a glass substrate or an encapsulation film. The first substrate 111 and the second substrate 112 can be made of a transparent material, or an opaque material.

The transparent display panel 110 can be categorized into a display area DA (or active area) in which pixels P are formed to display an image, and a non-display area NDA (or non-active area) for not displaying an image.

First signal lines SL1, second signal lines SL2 and pixels P can be provided in the display area DA, and a pad area PA in which pads are disposed and at least one scan driver 205 can be provided in the non-display area NDA.

The first signal lines SL1 can be extended in a second direction (e.g., Y-axis direction), and can cross the second signal lines SL2 in the display area DA. The second signal lines SL2 can be extended in a first direction (or X-axis direction). The pixels can be disposed in an area where the first signal line SL1, an area in which the second signal line SL2 is provided, or an area where the first signal line SL1 and the second signal line SL2 cross each other, and can emit predetermined light to display an image.

A plurality of pads can be disposed in the pad area PA. As an example, a size of the first substrate 111 can be greater than that of the second substrate 112, therefore, a portion of the first substrate 111 can be exposed without being covered by the second substrate 112, without being limited thereto. Pads such as power pads and data pads can be provided in a portion of the first substrate 111, which is exposed without being covered by the second substrate 112.

The scan driver 205 is connected to scan lines to supply scan signals. The scan driver 205 can be formed in the non-display area NDA outside one side or both sides of the display area DA of the transparent display panel 110 in a gate driver in panel (GIP) mode. Alternatively, the scan driver 205 can be manufactured as a driving chip, packaged on a flexible film and attached to the non-display area NDA outside one side or both sides of the display area DA of the transparent display panel 110 in a tape automated bonding (TAB) mode, or can be attached to the non-display area NDA using a chip-on-glass (COG) or chip-on-panel (COP) method, or can be implemented using a chip-on-film (COF) method and connected to the display panel 110, without being limited thereto.

The source drive IC 210 receives digital video data and a data control signal from the timing controller 240. The source drive IC 210 converts digital video data into analog data voltages in accordance with a data control signal and supplies the analog data voltages to the data lines. When the source drive IC 210 is manufactured as a driving chip, the source drive IC 210 can be packaged on the flexible film 220 by a chip on film (COF) mode or a chip on plastic (COP) mode, without being limited thereto.

Lines for connecting the pads to the source drive IC 210 and lines for connecting the pads to lines of the circuit board 230 can be formed in the flexible film 220. The flexible film 220 is attached onto the pads, for example, by using an anisotropic conducting film, so that the pads and the lines of the flexible film 220 can be connected to each other.

The circuit board 230 can be attached to the flexible films 220. A plurality of circuits implemented with driving chips can be packaged on the circuit board 230. For example, the timing controller 240 can be packaged on the circuit board 230. The circuit board 230 can be a printed circuit board or a flexible printed circuit board.

The timing controller 240 receives digital video data and a timing signal from an external system board (not shown). The timing controller 240 generates a scan control signal for controlling the operation timing of the scan driver and a data control signal for controlling the source drive ICs 210 based on the timing signal. The timing controller 240 supplies the scan control signal to the scan driver 205, and supplies the data control signal to the source drive ICs 210.

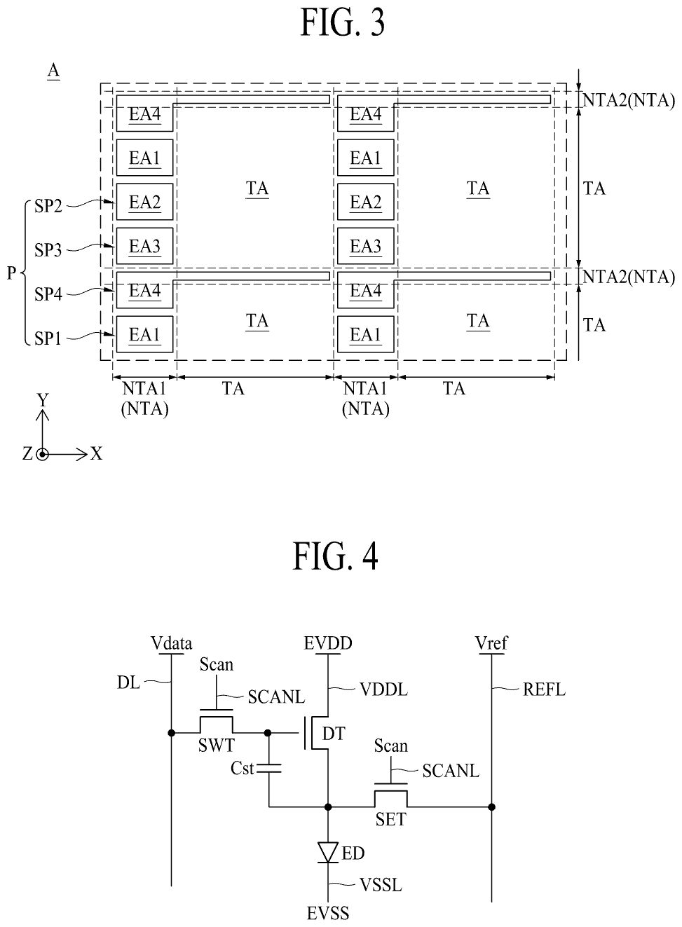

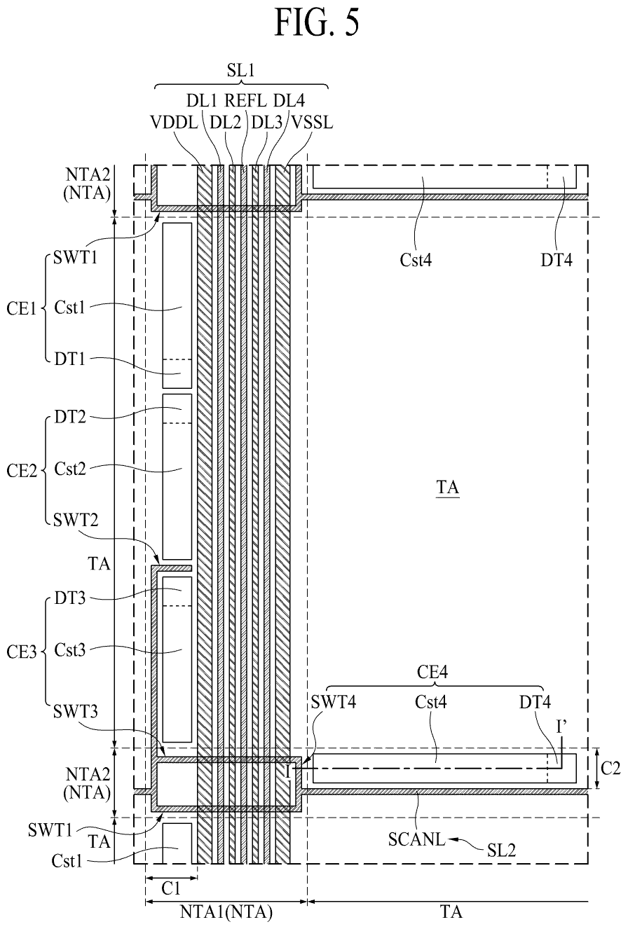

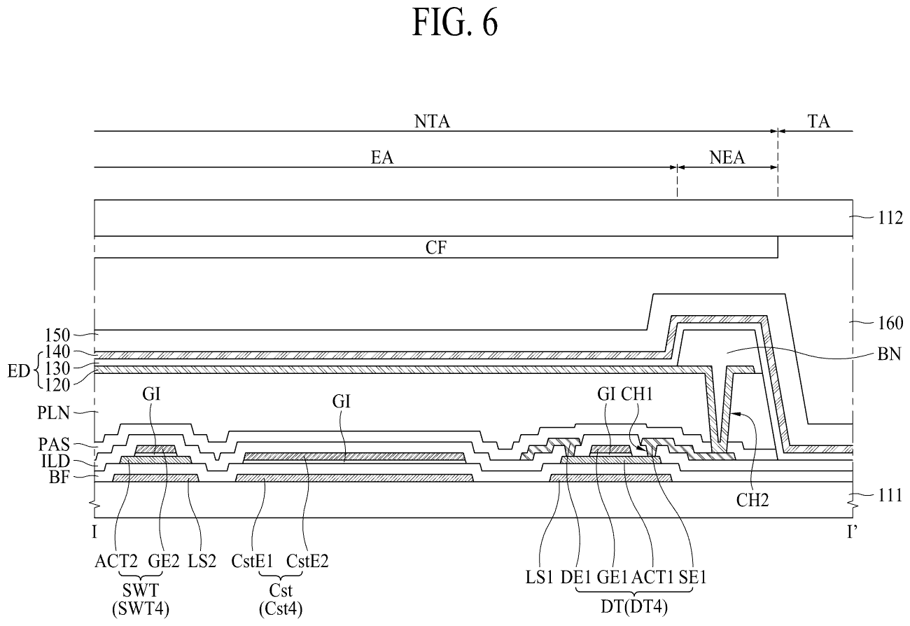

FIG. 3 is a schematic view illustrating one exemplary embodiment of a pixel provided in an area A of FIG. 2, FIG. 4 is a circuit view illustrating an example of a pixel element of a subpixel shown in FIG. 3, FIG. 5 is a schematic view illustrating an example in which a plurality of signal lines and circuit elements are disposed, and FIG. 6 is a cross-sectional view illustrating an example of an area along line I-I′ of FIG. 5.

The transparent display panel 110 according to one exemplary embodiment of the present disclosure can be categorized into a display area DA in which pixels P are formed to display an image, and a non-display area NDA (FIG. 2) for not displaying an image.

The display area DA can include a first area NTA in which a plurality of subpixels SP1, SP2, SP3 and SP4 are disposed, and a second area TA in which the plurality of subpixels SP1, SP2, SP3 and SP4 are not disposed, as shown in FIG. 3. The first area NTA can be a non-transmissive area that does not transmit most of light incident from the outside. The second area TA can be a transmissive area through which most of light incident from the outside passes. For example, the transmissive area TA can be an area in which light transmittance is greater than α%, and the non-transmissive area NTA can be an area in which light transmittance is smaller than β%. In this case, α can be a value greater than β. A user can view an object or a background, which is positioned on a rear surface of the transparent display panel 110, due to the transmissive areas TA.

The non-transmissive area NTA can include a first non-transmissive area NTA1 and a second non-transmissive area NTA2, and a plurality of pixels P and a plurality of first signal lines SL1 and a plurality of second signal lines SL2 for supplying signals to each of the plurality of pixels P can be disposed in the non-transmissive area NTA.

As an example, the first non-transmissive area NTA1 can be disposed between the transmissive areas TA disposed to be adjacent to each other in the first direction (e.g., X-axis direction) as shown in FIG. 3. The first non-transmissive area NTA1 can be extended in the second direction (e.g., Y-axis direction) between the transmissive areas TA disposed to be adjacent to each other in the first direction (e.g., X-axis direction), and can be disposed to overlap at least a portion of light emission areas EA1, EA2, EA3 and EA4. A plurality of first non-transmissive areas NTA1 can be disposed to be spaced apart from each other in the transparent display panel 110, and the transmissive area TA can be provided between two adjacent first non-transmissive areas NTA1. Embodiments are not limited thereto. As an example, the first non-transmissive area NTA1 can be disposed between the transmissive areas TA disposed to be adjacent to each other in the second direction (e.g., Y-axis direction), or in a direction other than the first and second directions. In addition, although a plurality of subpixels SP1, SP2, SP3 and SP4 are arranged in a line in the second direction (e.g., Y-axis direction) in the first non-transmissive area NTA1, embodiments are not limited thereto. As an example, a plurality of subpixels SP1, SP2, SP3 and SP4 can be arranged in a line in the first direction (e.g., X-axis direction) or in a direction other than the first and second directions in the first non-transmissive area NTA1. As an example, a plurality of subpixels SP1, SP2, SP3 and SP4 can be arranged in two or more lines in the first or second direction or a direction other than the first and second directions in the first non-transmissive area NTA1. As an example, two or more subpixels can be arranged in the first non-transmissive area NTA1 in one pixel, without being limited thereto.

The second non-transmissive area NTA2 can be disposed between the transmissive areas TA disposed to be adjacent to each other in the second direction (e.g., Y-axis direction) as shown in FIG. 3. The second non-transmissive area NTA2 can be extended in the first direction (e.g., X-axis direction) between the transmissive areas TA disposed to be adjacent to each other in the second direction (e.g., Y-axis direction), and can be disposed to overlap at least a portion of the light emission areas EA1, EA2, EA3 and EA4. A plurality of second non-transmissive areas NTA2 can be disposed to be spaced apart from each other in the transparent display panel 110, and the transmissive area TA can be provided between two adjacent second non-transmissive areas NTA2.

As an example, the transmissive area TA can be surrounded by two first non-transmissive areas NTA1 and two second non-transmissive areas NTA2, without being limited thereto.

A plurality of pixels P can be disposed in the first and second non-transmissive areas NTA1 and NTA2. Each pixel P can include at least two subpixels. For example, each pixel P can include a first subpixel SP1, a second subpixel SP2 and a third subpixel SP3, but is not limited thereto. Each pixel P can further include a fourth subpixel SP4.

The first subpixel SP1 can include a first light emission area EA1 that emits light of a first color, and the second subpixel SP2 can include a second light emission area EA2 that emits light of a second color. The third subpixel SP3 can include a third light emission area EA3 that emits light of a third color, and the fourth subpixel SP4 can include a fourth light emission area EA4 that emits light of a fourth color. As an example, the first to fourth colors can be different from each other, or at least two of the first to fourth colors can be the same color.

The first to fourth light emission areas EA1, EA2, EA3 and EA4 can emit light of different colors. For example, the first light emission area EA1 can emit red light, and the second light emission area EA2 can emit green light. The third light emission area EA3 can emit blue light, and the fourth light emission area EA4 can emit white light. However, the present disclosure is not limited to the above example. Also, various modifications can be made in the arrangement order of the subpixels SP1, SP2, SP3 and SP4.

The plurality of subpixels SP1, SP2, SP3 and SP4 can be disposed in the first non-transmissive area NTA1 and the second non-transmissive area NTA2 to display an image.

Each of the plurality of subpixels SP1, SP2, SP3 and SP4 can include a light emitting element ED for emitting light and a circuit element as shown in FIG. 4. In detail, each of the plurality of subpixels SP1, SP2, SP3 and SP4 can include a circuit clement having a 3T (Transistor) 1C (capacitor) structure that includes a switching transistor SWT, a sensing transistor SET, a driving transistor DT and a capacitor Cst, and a light emitting element ED, but is not limited thereto. Each of the subpixels SP1, SP2, SP3 and SP4 can further include a compensation circuit, and in this case, can have various structures such as 4T2C, 5T2C, 6T1C, 6T2C, 7T1C, 7T1C and 7T2C.

Each of the transistors DT, SWT and SET of each of the subpixels SP1, SP2, SP3 and SP4 can include a gate electrode, a source electrode, and a drain electrode. Since the source electrode and the drain electrode are not fixed and can be changed in accordance with a voltage, which are applied to the gate electrode, and a current direction, one of the source electrode and the drain electrode can be expressed as a first electrode, and the other can be expressed as a second electrode. The transistors DT, SWT and SET of each of the subpixels SP1, SP2, SP3 and SP4 can use at least one of a polysilicon semiconductor, an amorphous silicon semiconductor, a compound semiconductor, an organic material, or an oxide semiconductor, without being limited thereto. The transistors DT, SWT and SET can be P-type or N-type transistors, or P-type and N-type transistors can be used interchangeably.

The switching transistor SWT can serve to supply a data voltage Vdata supplied from a data line DL to the driving transistor DT. In detail, the switching transistor SWT can charge the capacitor Cst with the data voltage Vdata supplied from the data line DL. To this end, the switching transistor SWT can have a gate electrode connected to a scan line SCANL and a first electrode connected to the data line DL. Also, the first switching transistor SWT can have a second electrode connected to one end of the capacitor Cst and the gate electrode of the driving transistor DT.

The switching transistor SWT can be turned on in response to a scan signal Scan applied through the scan line SCANL. When the switching transistor SWT is turned on, the data voltage Vdata applied through the data line DL can be transferred to one end of the capacitor Cst.

The sensing transistor SET can serve to supply a reference voltage Vref supplied from a reference line REFL to the driving transistor DT. In detail, the sensing transistor SET can have a gate electrode connected to the scan line SCANL and a first electrode connected to the reference line REFL. Also, the sensing transistor SET can have a second electrode connected to the first electrode of the driving transistor DT and the other end of the capacitor Cst.

The sensing transistor SET can be turned on in response to the scan signal Scan applied through the scan line SCANL. When the sensing transistor SET is turned on, the reference voltage Vref (or an initialization voltage) applied through the reference line REFL can be transferred to the other end of the capacitor Cst. Also, the reference voltage Vref can be applied to the first electrode of the driving transistor DT. Although it is illustrated that the gate electrodes of the sensing transistor SET and the switching transistor SWT are connected to the same scan line SCANL and thereby the sensing transistor SET and the switching transistor SWT can be turned on in response to the same scan signal Scan, embodiments are not limited thereto. As an example, the gate electrodes of the sensing transistor SET and the switching transistor SWT can be connected to different scan lines and thereby the sensing transistor SET and the switching transistor SWT can be controlled independently, without being limited thereto.

The capacitor Cst can serve to maintain the data voltage Vdata supplied to the driving transistor DT during a certain period (e.g., one frame). In detail, the capacitor Cst can have a first electrode connected to the gate electrode of the driving transistor DT and a second electrode connected to the first electrode of the driving transistor DT. The capacitor Cst can charge a driving voltage Vgs corresponding to the data voltage Vdata transferred through the switching transistor SWT and supply the charged driving voltage Vgs to the driving transistor DT.

The driving transistor DT can serve to generate a driving current Ids from a first power source EVDD supplied from a pixel power source line VDDL and supply the driving current Ids to an anode electrode of the light emitting element ED. The driving transistor DT can have a gate electrode connected to one end of the capacitor Cst and a second electrode connected to the pixel power source line VDDL. Also, the driving transistor DT can have a first electrode connected to the anode electrode of the light emitting element ED.

The driving transistor DT can be turned on in accordance with a driving voltage Vgs charged in the capacitor Cst. When the driving transistor DT is turned on, the first power source EVDD applied through the pixel power line VDDL can be transferred to the anode electrode of the light emitting element ED. The driving transistor DT can control light emission intensity of the light emitting element ED by controlling the driving current Ids in accordance with the driving voltage Vgs charged in the capacitor Cst.

The light emitting element ED can include an anode electrode connected to the driving transistor DT, a cathode electrode receiving a second power source EVSS from the common power line VSSL, and a light emitting layer between the anode electrode and the cathode electrode. As an example, the anode electrode is an independent electrode for each light emitting element, but the cathode electrode can be a common electrode shared by at least some or all of the light emitting elements. Embodiments are not limited thereto. As an example, the cathode electrode can be also an independent electrode for each light emitting element. When the driving current Ids is supplied from the driving transistor DT, electrons from the cathode electrode can be injected into the light emitting layer and holes from the anode electrode can be injected into the light emitting layer, so that the light emitting element ED can allow fluorescent or phosphorescent materials to emit light through recombination of the electrons and the holes in the light emitting layer, thereby generating light of brightness proportional to a current value of the driving current.

The anode electrode of the light emitting element ED can be connected to the first electrode of the driving transistor DT, and the cathode electrode thereof can be connected to the common power line VSSL. The light emitting element ED can emit light to correspond to the driving current Ids generated by the driving transistor DT.

In the transparent display panel 110, as an example, the circuit elements DT, SWT, SET and Cst shown in FIG. 4 and the plurality of signal lines DL, VDDL, VSSL, REFL and SCANL can be disposed to overlap the light emission areas EA1, EA2, EA3 and EA4 (see FIG. 3) in order to increase an aperture ratio. without being limited thereto.

Referring to FIG. 5, the first signal line SL1 can be disposed in the first non-transmissive area NTA1. The first signal line SL1 can be extended in the second direction (e.g., Y-axis direction) in the first non-transmissive area NTA1.

The first signal line SL1 can include a plurality of lines, and in this case, one first signal line SL1 can mean a signal line group formed of the plurality of lines. For example, one first signal line SL1 can mean a signal line group formed of four data lines DL1, DL2, DL3 and DL4, a pixel power line VDDL, a reference line REFL, and a common power line VSSL.

The first signal line SL1 can include, for example, at least one of a pixel power line VDDL, a common power line VSSL, a reference line REFL, or data lines DL.

The pixel power line VDDL can supply a first power source to the driving transistor DT of each of the subpixels SP1, SP2, SP3 and SP4 disposed in the first and second non-transmissive areas NTA1 and NTA2.

The common power line VSSL can supply a second power source to the cathode electrodes of the subpixels SP1, SP2, SP3 and SP4 disposed in the first and second non-transmissive areas NTA1 and NTA2. In this case, the second power source can be a common power source commonly supplied to the subpixels SP1, SP2, SP3 and SP4.

The reference line REFL can supply an initialization voltage (or a reference voltage) to the driving transistor DT of each of the subpixels SP1, SP2, SP3 and SP4 disposed in the first and second non-transmissive areas NTA and NTA2. As an example, the reference line REFL can be disposed between the plurality of data lines DL1, DL2, DL3 and DL4. For example, the reference line REFL can be disposed at the center of the plurality of data lines DL1, DL2, DL3 and DL4, for example, between the second data line DL2 and the third data line DL3. Embodiments are not limited thereto. As an example, the reference line REFL can be disposed between any one of the plurality of DL1, DL2, DL3 and DL4 and the remaining data lines of the plurality of DL1, DL2, DL3 and DL4. As an example, the reference line REFL can be disposed at one side of all of the plurality of DL1, DL2, DL3 and DL4.

Each of the data lines DL1, DL2, DL3 and DL4 can supply a data voltage to each of the subpixels SP1, SP2, SP3 and SP4 disposed in the first and second non-transmissive areas NTA1 and NTA2. For example, the first data line DL1 can supply a first data voltage to the first subpixel SP1 disposed in the first non-transmissive area NTA1, the second data line DL2 can supply a second data voltage to the second subpixel SP2 disposed in the first non-transmissive area NTA1, the third data line DL3 can supply a third data voltage to the third subpixel SP3 disposed in the first non-transmissive area NTA1, and the fourth data line DL4 can supply a fourth data voltage to the fourth subpixel SP4 disposed in the second non-transmissive area NTA2.

The second signal line SL2 can be disposed in the second non-transmissive area NTA2. The second signal line SL2 can be extended in the first direction (e.g., X-axis direction) in the second non-transmissive area NTA2.

The second signal line SL2 can include a plurality of lines, and in this case, one second signal line SL2 can mean a signal line group formed of a plurality of lines.

The second signal line SL2 can include, for example, a scan line SCAN. The scan line SCANL can supply a scan signal to the subpixels SP1, SP2, SP3 and SP4 disposed in the first and second non-transmissive areas NTA1 and NTA2.

The circuit elements DT, SWT, SET and Cst for the plurality of subpixels SP1, SP2, SP3 and SP4 can be divided into a first circuit portion C1 disposed in the first non-transmissive area NTA1 and a second circuit portion C2 disposed in the second non-transmissive area NTA2.

The first circuit portion C1 can include a plurality of circuit elements for driving each of the plurality of subpixels disposed in the first non-transmissive area NTA1. For example, three subpixels SP1, SP2 and SP3 can be disposed in the first non-transmissive area NTA1 as shown in FIG. 3. In this case, the first circuit portion C1 can include three circuit elements CE1, CE2 and CE3 for respectively driving the three subpixels SP1, SP2 and SP3 as shown in FIG. 5. In more detail, the first circuit portion C1 can include a first circuit element CE1 for driving the first subpixel SP1, a second circuit element CE2 for driving the second subpixel SP2, and a third circuit element CE3 for driving the third subpixel SP3, but the present disclosure is not limited thereto. For convenience of description, the following description will be based on that the first circuit portion C1 includes first to third circuit elements CE1, CE2 and CE3 for respectively driving the first to third subpixels SP1, SP2 and SP3.

The first circuit portion C1 can be disposed on one side of the first signal line SL1. In the transparent display panel 110 according to one exemplary embodiment of the present disclosure, a plurality of circuit elements CE1, CE2 and CE3 included in the first circuit portion C1 can be disposed to be collected on one side of the first signal line SL1. As an example, a first signal line area, in which the first signal line SL1 is disposed, can be disposed between the first circuit portion C1 and the transmissive area TA. As an example, the first circuit portion C1 can be disposed in an edge area of one side of the subpixels SP1, SP2 and SP3. The first circuit portion C1 can be formed along an edge area in the edge area of one side of the first non-transmissive area NTA1. In detail, the first circuit portion C1 can be formed along an edge area in one side of the first non-transmissive area NTA1. Although it is illustrated that the first circuit portion C1 is disposed on a left side of the first signal line SL1, the embodiments are not limited thereto. As an example, the first circuit portion C1 can be disposed on a right side of the first signal line SL1, or, the first circuit portion C1 can be disposed between signal lines among the first signal line SL1, without being limited thereto. As another example, the first circuit portion C1 can at least partially overlap the first signal line SL1, without being limited thereto.

The circuit element can include a switching transistor SWT, a sensing transistor SET (see FIG. 4), a driving transistor DT and a capacitor Cst, and can be provided for each of the subpixels SP1, SP2 and SP3. The first circuit element CE1 connected to the first subpixel SP1 can include a first driving transistor DT1, a first switching transistor SWT1, a first sensing transistor SET (see FIG. 4), and a first capacitor Cst1. The second circuit element CE2 connected to the second subpixel SP2 can include a second driving transistor DT2, a second switching transistor SWT2, a second sensing transistor SET (see FIG. 4), and a second capacitor Cst2. The third circuit element CE3 connected to the third subpixel SP3 can include a third driving transistor DT3, a third switching transistor SWT3, a third sensing transistor SET (see FIG. 4), and a third capacitor Cst3.

In the transparent display panel 110 according to one exemplary embodiment of the present disclosure, the first signal line SL1 and the first circuit portion C1 can be disposed not to overlap each other, so that a size of an area in which the plurality of signal lines DL, VDDL, VSSL and REFL included in the first circuit portion C1 and the circuit elements CE1, CE2 and CE3 included in the first circuit portion C1 are formed can be reduced or minimized. When the circuit elements CE1, CE2 and CE3 are disposed between the plurality of signal lines DL, VDDL, VSSL and REFL included in one first signal line SL1, the circuit elements CE1, CE2 and CE3 can need a space for making sure of a minimum gap distance from the plurality of signal lines DL, VDDL, VSSL and REFL on at least one of or each of upper, lower, left and right sides. For this reason, a size of an area in which the plurality of signal lines DL, VDDL, VSSL and REFL and the circuit elements CE1, CE2 and CE3 are formed can be increased.

In the transparent display panel 110 according to one exemplary embodiment of the present disclosure, the circuit elements CE1, CE2 and CE3 can be disposed to be collected on one side of the first signal line SL1, so that a space for separating the circuit elements CE1, CE2 and CE3 from the plurality of signal lines DL, VDDL, VSSL and REFL can be reduced or minimized.

The first to third subpixels SP1, SP2 and SP3 can be arranged in a row along the second direction (e.g., Y-axis direction) in the first non-transmissive area NTA1, as shown in FIG. 3. The first to third circuit elements CE1, CE2 and CE3 for each of the first to third subpixels SP1, SP2 and SP3 can be arranged in the second direction (e.g., Y-axis direction) along one edge area of each of the plurality of subpixels SP1, SP2 and SP3. For example, the first to third circuit elements CE1, CE2 and CE3 can be arranged in a row in the second direction (e.g., Y-axis direction) as shown in FIG. 5. In addition, switching transistors SWT1, SWT2 and SWT3, driving transistors DT1, DT2 and DT3 and capacitors Cst1, Cst2 and Cst3, which are respectively included in the first to third circuit elements CE1, CE2 and CE3, can be also arranged in a row in the second direction (e.g., Y-axis direction).

The second circuit portion C2 can include at least one circuit element for driving at least one subpixel disposed in the second non-transmissive area NTA2. For example, one subpixel SP4 can be disposed in the second non-transmissive area NTA2, as shown in FIG. 3. In this case, the second circuit portion C2 can include one circuit element CE4 for driving one subpixel SP4, as shown in FIG. 5. In detail, the second circuit portion C2 can include the fourth circuit element CE4 for driving the fourth subpixel SP4, but is not limited thereto. For convenience of description, the following description will be based on that the second circuit portion C2 includes the fourth circuit element CE4 for driving the fourth subpixel SP4.

The second circuit portion C2 can be disposed on one side of the second signal line SL2. In the transparent display panel 110 according to one exemplary embodiment of the present disclosure, the circuit element CE4 included in the second circuit portion C2 can be disposed on one side of the second signal line SL2. The second circuit portion C2 can be disposed between a second signal line area, in which the second signal line SL2 is disposed, and the transmissive area TA. The second circuit portion C2 can be disposed in an edge area of one side of the subpixel SP4. The second circuit portion C2 can be formed along an edge area in the edge area of one side of the second non-transmissive area NTA2. In detail, the second circuit portion C2 can be formed along an edge area in one side of the second non-transmissive area NTA2. Although it is illustrated that the second circuit portion C2 is disposed on the upper side of the second signal line SL2, embodiments are not limited thereto. As an example, the second circuit portion C2 can be disposed on the lower side of the second signal line SL2.

The fourth circuit element CE4 connected to the fourth subpixel SP4 can include a fourth driving transistor DT4, a fourth switching transistor SWT4, a fourth sensing transistor SET (see FIG. 4), and a fourth capacitor Cst4.

In the transparent display panel 110 according to one exemplary embodiment of the present disclosure, the second signal line SL2 and the second circuit portion C2 can be disposed not to overlap each other, thereby reducing or minimizing a size of an area in which the signal line SCANL included in the second signal line SL2 and the circuit element CE4 included in the second circuit portion C2 are formed.

The fourth subpixel SP4 can be formed to be long in the first direction (e.g., X-axis direction) in the second non-transmissive area NTA2 as shown in FIG. 3. The fourth circuit element CE4 for the fourth subpixels SP4 can be disposed to be long in the first direction (e.g., X-axis direction) along an edge area of one side of the fourth subpixel SP4. For example, the fourth switching transistor SWT4, the fourth driving transistor DT4 and the fourth capacitor Cst4, which are included in the fourth circuit element CE4, can be arranged in a row in the first direction (e.g., X-axis direction).

Hereinafter, the switching transistor SWT, the driving transistor DT, and the capacitor Cst will be described in more detail with reference to FIG. 6.

The switching transistor SWT, the driving transistor DT and the capacitor Cst can be arranged in a row in an edge area of one side of at least one of the subpixels SP1, SP2, SP3 and SP4. Each of the driving transistors DT can include an active layer ACT1, a gate electrode GE1, a source electrode SE1, and a drain electrode DE1, and the switching transistor SWT can include an active layer ACT2 and a gate electrode GE2. The capacitor electrode Cst can include a first capacitor electrode CstE1 and a second capacitor electrode CstE2. Although it is illustrated that the switching transistor SWT and the driving transistor DT are disposed on the same layer and have similar structures, embodiments are no limited thereto. As an example, the switching transistor SWT and the driving transistor DT can be disposed on different layers and/or can have different structures.

In more detail, as an example, light shielding layers LS1 and LS2 and the first capacitor electrode CstE1 can be provided on the first substrate 111. The light shielding layer LS1 can be provided in an area in which the driving transistor DT is formed, to shield external light incident on the active layer ACT1 of the driving transistor DT. Also, the light shielding layer LS2 can be provided in an area in which the switching transistor SWT is formed, to shield external light incident on the active layer ACT2 of the switching transistor SWT. Embodiments are not limited thereto. As an example, one or both of the light shielding layers LS1 and LS2 can be omitted, or can be disposed on a different layer.

The first capacitor electrode CstE1 can be provided on the same layer as the light shielding layer LS. As an example, the first capacitor electrode CstE1 can be disposed between or can be not disposed between the light shielding layer LS1 provided in the area in which the driving transistor DT is formed and the light shielding layer LS2 provided in the area in which the switching transistor SWT is formed, without being limited thereto.

At least one of or each of the light shielding layers LS1 and LS2 and the first capacitor electrode CstE1 can be formed of a single layer or multi-layer made of any one of molybdenum (Mo), aluminum (Al), chromium (Cr), gold (Au), titanium (Ti), nickel (Ni), neodymium (Nd) and copper (Cu), or their alloy, without being limited thereto.

A buffer layer BF can be provided on the light shielding layers LS1 and LS2. The buffer layer BF is to protect the driving transistor DT, the switching transistor SWT and the capacitor Cst that is vulnerable to moisture permeation, from impurities such as hydrogen and moisture, which are permeated through the first substrate 111, and can have a single layered structure or a multi-layered structure, which includes an inorganic insulating material such as silicon oxide (SiOx), silicon nitride (SiNx) and aluminum oxide (Al₂O₃). As shown in FIG. 6, the buffer layer BF can include not only the non-transmissive area NTA but also the transmissive area TA, but is not limited thereto. In another embodiment, the buffer layer BF can be provided only in the non-transmissive area NTA, and cannot be provided in the transmissive area NTA.

As an example, the driving transistor DT, the switching transistor SWT and the second capacitor electrode CstE2 can be disposed on the buffer layer BF, without being limited thereto. As an example, the active layer ACT1 of the driving transistor DT and the active layer ACT2 of the switching transistor SWT can be disposed on the buffer layer BF, without being limited thereto. As an example, the active layer ACT1 of the driving transistor DT and the active layer ACT2 of the switching transistor SWT can be disposed on different layers. As an example, each of the active layer ACT1 of the driving transistor DT and the active layer ACT2 of the switching transistor SWT can be formed of a silicon-based semiconductor material or an oxide-based semiconductor material, without being limited thereto. As an example, each of the active layer ACT1 of the driving transistor DT and the active layer ACT2 of the switching transistor SWT can be formed of any other semiconductor materials such as a compound semiconductor material, an organic semiconductor material, a germanium-based semiconductor material, etc. As an example, the active layer ACT1 of the driving transistor DT and the active layer ACT2 of the switching transistor SWT can be formed of the same material or different materials.

A gate insulating layer GI can be disposed on the active layer ACT1 of the driving transistor DT and the active layer ACT2 of the switching transistor SWT. As shown in FIG. 6, the gate insulating layer GI can be formed to be patterned only in an area in which the gate electrode GE1 of the driving transistor DT, the gate electrode GE2 of the switching transistor SWT, and the second capacitor electrode CstE2 are provided, but is not limited thereto. In another exemplary embodiment, the gate insulating layer GI can be formed to cover the active layer ACT1 of the driving transistor DT and the active layer ACT2 of the switching transistor SWT. The gate insulating layer GI can have a single-layered structure or a multi-layered structure, which includes an inorganic insulating material such as silicon oxide (SiOx), silicon nitride (SiNx), and aluminum oxide (Al₂O₃), without being limited thereto.

The gate electrode GE1 of the driving transistor DT, the gate electrode GE2 of the switching transistor SWT, and the second capacitor electrode CstE2 can be provided on the gate insulating layer GI, or can be provided on different layers. The gate electrode GE1 of the driving transistor DT, the gate electrode GE2 of the switching transistor SWT, and the second capacitor electrode CstE2 can be formed of a single layer or multi-layer made of any one of molybdenum (Mo), aluminum (Al), chromium (Cr), gold (Au), titanium (Ti), nickel (Ni), neodymium (Nd) and copper (Cu), or their alloy, without being limited thereto.

An interlayer insulating layer ILD can be provided on the gate electrode GE1 of the driving transistor DT, the gate electrode GE2 of the switching transistor SWT, and the second capacitor electrode CstE2. The interlayer insulating layer ILD can have a single-layered structure or a multi-layered structure, which includes an inorganic insulating material such as silicon oxide (SiOx), silicon nitride (SiNx) and aluminum oxide (Al₂O₃), without being limited thereto.

The source electrode SE1 and a drain electrode DE1 of the driving transistor DT can be disposed on the interlayer insulating layer ILD. The source electrode SE1 and the drain electrode DE1 of the driving transistor DT can be connected to a source area and a drain area of the active layer ACT1 respectively, through a first contact hole CH1 passing through the interlayer insulating layer ILD. The source electrode SE1 and the drain electrode DE1 of the driving transistor DT can be formed of a single layer or multi-layer made of any one of molybdenum (Mo), aluminum (Al), chromium (Cr), gold (Au), titanium (Ti), nickel (Ni), neodymium (Nd) and copper (Cu), or their alloy, without being limited thereto.

Meanwhile, as an example, one of the source electrode SE1 and the drain electrode DE1 of the driving transistor DT can be connected to the light shielding layer LS1 through a contact hole passing through the interlayer insulating layer ILD and the buffer layer BF. The light shielding layer LS1 can be electrically connected to one of the source electrode SE1 and the drain electrode DE1 of the driving transistor DT, and thus cannot operate as a floating gate. When the light shielding layer LS1 is floated without being connected to the other electrodes, a threshold voltage of the driving transistor DT can be changed by the floating light shielding layer LS1. In the transparent display panel 110 according to one exemplary embodiment of the present disclosure, the light shielding layer LS1 can be electrically connected to one of the source electrode SE1 and the drain electrode DE1 of the driving transistor DT, whereby a change in the threshold voltage of the driving transistor DT can be reduced or minimized. Embodiments are not limited thereto. As an example, the light shielding layer LS1 cannot be electrically connected to the source electrode SE1 or the drain electrode DE1 of the driving transistor DT, but can be electrically connected to another electrode or signal line or another pad, or can be floated, without being limited thereto. As an example, the light shielding layer LS1 can be omitted depending on the design.

An insulating layer PAS can be provided on the driving transistor DT, the switching transistor SWT and the capacitor Cst. The insulating layer PAS can be provided in the non-transmissive area NTA, and cannot be provided in at least a portion of the transmissive area TA. As an example, the insulating layer PAS can include an opening area that overlaps at least a portion or the entirety of the transmissive area TA. The insulating layer PAS can deteriorate transparency by causing refraction of light when the light is transmitted. Therefore, the transparent display panel 110 according to one exemplary embodiment of the present disclosure can increase transparency by removing a portion of the insulating layer PAS from the transmissive area TA. The insulating layer PAS can have a single-layered structure or a multi-layered structure, which includes an inorganic insulating material such as silicon oxide (SiOx), silicon nitride (SiNx) and aluminum oxide (Al₂O₃), without being limited thereto.

A planarization layer PLN for planarizing a step difference due to the driving transistor DT, the switching transistor SWT and the capacitor Cst can be provided on the insulation layer PAS. The planarization layer PLN can be provided in the non-transmissive area NTA, and cannot be provided in at least a portion of the transmissive area TA. As an example, the planarization layer PLN can include an opening area that overlaps at least a portion or the entirety of the transmissive area TA. The planarization layer PLN can deteriorate transparency by causing refraction of light when the light is transmitted. Therefore, the transparent display panel 110 according to one exemplary embodiment of the present disclosure can increase transparency by removing a portion of the planarization layer PLN from the transmissive area TA. The planarization layer PLN can be formed of an organic layer such as an acrylic resin, an epoxy resin, a phenolic resin, a polyamide resin, or a polyimide resin, without being limited thereto.

Light emitting elements ED, which include a first electrode 120, a light emitting layer 130 and a second electrode 130, and a bank BN can be provided on the planarization layer PLN.

The first electrode 120 can be disposed in the non-transmissive area NTA. The first electrode 120 can be provide for each of the subpixels SP1, SP2, SP3 and SP4 on the planarization layer PLN. The first electrodes 120 provided for each of the subpixels SP1, SP2, SP3 and SP4 can be electrically insulated from each other by being spaced apart from each other.

The first electrode 120 can be electrically connected to the driving transistor DT. As an example, the first electrode 120 can be connected to one of the source electrode SE1 and the drain electrode DE1 of the driving transistor DT through a second contact hole CH2 passing through the planarization layer PLN and the insulating layer PAS.

The first electrode 120 can be formed of a conductive material. As an example, the first electrode 120 can be formed of a metal material. As an example, the first electrode 120 can be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO, without being limited thereto. The Ag alloy can be an alloy of silver (Ag), palladium (Pd), copper (Cu) and the like. The MoTi alloy can be an alloy of molybdenum (Mo) and titanium (Ti). The first electrode 120 can be an anode electrode of the light emitting element ED.

The bank BN can be provided on the planarization layer PLN in the non-transmissive area NTA. As an example, the bank BN can be formed to cover an edge of each of the first electrodes 120 and expose a portion of each of the first electrodes 120, without being limited thereto. Therefore, the bank BN can mitigate or prevent a limitation in which the light emission efficiency is deteriorated due to the concentration of current at the ends of the first electrodes 120. Embodiments are not limited thereto. As an example, the bank BN can be formed to be adjacent to and contact the edge of each of the first electrodes 120, without being limited thereto.

The bank BN can define a light emission area EA of each of the subpixels SP1, SP2, SP3 and SP4. The light emission area EA of each of the subpixels SP1, SP2, SP3 and SP4 represents an area where the first electrode 120, the light emitting layer 130 and the second electrode 140 are sequentially stacked to emit light by combination of holes from the first electrode 120 and electrons from the second electrode 140 in the light emitting layer 130. In this case, the area where the bank BN is formed does not emit light, and thus becomes the non-light emission area NEA, and the area where the bank BN is not formed and the first electrode 120 is exposed can become the light emission area EA.

The bank BN can be provided in the non-transmissive area NTA, and cannot be provided in at least a portion of the transmissive area TA. That is, the bank BN can include an opening area that overlaps at least a portion or the entirety of the transmissive area TA. The bank BN can deteriorate transparency by causing refraction of light when the light is transmitted. Therefore, the transparent display panel 110 according to one exemplary embodiment of the present disclosure can increase transparency by removing a portion of the bank BN from the transmissive area TA.

The bank BN can be formed of an organic layer such as an acrylic resin, an epoxy resin, a phenolic resin, a polyamide resin, or a polyimide resin, without being limited thereto.

The light emitting layer 130 can be provided on the first electrode 120. As an example, the light emitting layer 130 can include an emission material layer. As an example, the light emitting layer 130 can include a hole transporting layer, an emission material layer and an electron transporting layer. In this case, when a voltage is applied to the first electrode 120 and the second electrode 140, holes and electrons move to the light emitting layer through the hole transporting layer and the electron transporting layer, respectively, and are combined with each other in the light emitting layer to emit light. As an example, the light emitting layer 130 can further include additional layers such as a hole injecting layer and an electron injecting layer, etc.

In one exemplary embodiment, the light emitting layer 130 can be a common layer commonly formed in the subpixels SP1, SP2, SP3 and SP4. In this case, the light emitting layer can be a white light emitting layer for emitting white light. In this case, the light emitting layer 130 can be formed not only in the subpixels SP1, SP2, SP3 and SP4 but also in the non-light emission area NEA between the subpixels SP1, SP2, SP3 and SP4. The light emitting layer 130 can be continuously formed between the subpixels SP1, SP2, SP3 and SP4. Also, the light emitting layer 130 can be provided in the transmissive area TA as well as the non-transmissive area NTA that includes the light emission area EA and the non-light emission area NEA, but is not limited thereto. As an example, the light emitting layer 130 can be formed to be patterned only in the non-transmissive area NTA that includes the light emission area EA and the non-light emission area NEA.

In another exemplary embodiment, the emission material layer of the light emitting layer 130 can be formed for each of the subpixels SP1, SP2, SP3 and SP4. For example, a red light emitting layer for emitting red light can be formed in the first subpixel SP1, a green light emitting layer for emitting green light can be formed in the second subpixel SP2, a blue light emitting layer for emitting blue light can be formed in the third subpixel SP3, and a white light emitting layer for emitting white light can be formed in the fourth subpixel SP4. In this case, the emission material layer of the light emitting layer 130 cannot be formed in the transmissive area TA. However, a hole injection layer HIL, the hole transporting layer HTL, the electron transporting layer ETL and an electron injection layer EIL except for the emission material layer can be commonly formed in the subpixels SP1, SP2, SP3 and SP4, and can be also formed in the transmissive area TA. Embodiments are not limited thereto. As an example, at least one of or each of the hole injection layer HIL, the hole transporting layer HTL, the electron transporting layer ETL and the electron injection layer EIL can be also formed for each of the subpixels SP1, SP2, SP3 and SP4, without being limited thereto.

The second electrode 140 can be provided on the light emitting layer 130. The second electrode 140 can be a common layer commonly formed in the subpixels SP1, SP2, SP3 and SP4 to apply the same voltage. The second electrode 140 can be formed not only in the light emission areas EA of the subpixels SP1, SP2, SP3 and SP4 but also in the non-light emission area NEA between the subpixels SP1, SP2, SP3 and SP4. The second electrode 140 can be continuously formed between the subpixels SP1, SP2, SP3 and SP4.

Also, the second electrode 140 can be provided in the transmissive area TA as well as the non-transmissive area NTA that includes the light emission area EA and the non-light emission area NEA, but is not limited thereto. The second electrode 140 can be formed to be patterned only in the non-transmissive area NTA that includes the light emission area EA and the non-light emission area NEA.

As an example, the second electrode 140 can be formed of a transparent conductive material (TCO) such as ITO or IZO capable of transmitting light or a semi-transmissive conductive material such as magnesium (Mg), silver (Ag) or an alloy of magnesium (Mg) and silver (Ag), without being limited thereto. When the second electrode 140 is formed of a semi-transmissive metal material, as an example, light emission efficiency can be increased by a micro cavity. The second electrode 140 can be a cathode electrode of the light emitting element ED.

An encapsulation layer 150 can be provided on the light emitting elements ED. The encapsulation layer 150 can be formed on the second electrode 140 to cover the second electrode 140. The encapsulation layer 150 serves to limit or prevent oxygen or moisture from being permeated into the light emitting layer 130 and the second electrode 140. To this end, as an example, the encapsulation layer 150 can include at least one inorganic layer and further include at least one organic layer, without being limited thereto.

A color filter CF can be provided on one surface of the second substrate 112, which faces the first substrate 111. The color filter CF can be provided. The color filter CF can be formed to be patterned for each of the subpixels SP1, SP2, SP3 and SP4.

As an example, the color filter CF can include a first color filter, a second color filter, a third color filter, and a fourth color filter. The first color filter can be disposed to correspond to the light emission area EA1 of the first subpixel SP1, and can be a red color filter for transmitting red light. The second color filter can be disposed to correspond to the light emission area EA2 of the second subpixel SP2, and can be a green color filter for transmitting green light. The third color filter can be disposed to correspond to the light emission area EA3 of the third subpixel SP3, and can be a blue color filter for transmitting blue light. The fourth color filter can be disposed to correspond to the light emission area EA4 of the fourth subpixel SP4, and can be a transparent organic layer. As an example, the fourth color filter can be omitted depending on the design.

Although not shown in the drawing, a black matrix (not shown) can be provided between the color filters CF. The black matrix can be provided between the subpixels SP1, SP2, SP3 and SP4 to reduce or prevent color mixture from occurring between adjacent subpixels SP1, SP2, SP3 and SP4. Also, the black matrix can reduce or prevent light incident from the outside from being reflected on a plurality of signal lines, e.g., scan lines, data lines, pixel power lines, common power lines and reference lines, which are provided between the subpixels SP1, SP2, SP3 and SP4. As an example, the black matrix can be omitted depending on the design.

Also, as an example, the black matrix can be provided between the transmissive area TA and the plurality of subpixels SP1, SP2 and SP3 to reduce or prevent light emitted from each of the plurality of subpixels SP1, SP2 and SP3 from moving to the transmissive area TA. The black matrix cannot be provided between a portion of the plurality of subpixels, for example, the white subpixel and the transmissive area TA. When the fourth subpixel SP4 is a white subpixel for emitting white light, the white light generated from the fourth subpixel SP4 does not vary depending on a viewing angle. Therefore, since the black matrix is not provided between the fourth subpixel SP4 and the transmissive area TA, it is possible to improve transmittance and reduce light loss caused by the black matrix.

As an example, such a black matrix can include a material that absorbs light, for example, a black dye that absorbs all light of a visible wavelength band, without being limited thereto.

A filler 160 can be provided between the first substrate 111 provided with the light emitting elements ED and the second substrate 112 provided with the color filter CF and the black matrix. In this case, a thermosetting resin or a UV curable resin can be used as the filler 160, and the filler 160 can be formed of an organic material having adhesive properties. In one exemplary embodiment, the filler 160 can include a material that absorbs hydrogen, without being limited thereto.

In the transparent display panel 110 according to one exemplary embodiment of the present disclosure, the circuit elements CE1, CE2 and CE3 can be disposed to be collected on one side of the first signal line SL1, so that a space for separating the circuit elements CE1, CE2 and CE3 from the plurality of signal lines DL, VDDL, VSSL and REFL can be reduced or minimized. Therefore, in the transparent display panel 110 according to one exemplary embodiment of the present disclosure, a size of the area, in which the plurality of signal lines DL, VDDL, VSSL and REFL included in the first signal line SL1 and the circuit elements CE1, CE2 and CE3 included in the first circuit portion C1 are formed, can be reduced or minimized. The transparent display panel 110 according to one exemplary embodiment of the present disclosure can reduce or minimize a width of the first non-transmissive area NTA1 in the first direction (e.g., X-axis direction).

Also, in the transparent display panel 110 according to one exemplary embodiment of the present disclosure, at least one of the plurality of circuit elements CE1, CE2, CE3 and CE4 can be disposed in the second non-transmissive area NTA2. For example, in the transparent display panel 110, the fourth circuit element CE4 for the fourth subpixel SP4 can be disposed in the second non-transmissive area NTA2.

Unlike the transparent display panel 110 according to one exemplary embodiment of the present disclosure, a structure in which all of the plurality of circuit elements CE1, CE2, CE3 and CE4 are disposed in the first non-transmissive area NTA1 can be considered. In this structure, since the plurality of signal lines DL, VDDL, VSSL and REFL and the plurality of circuit elements CE1, CE2, CE3 and CE4 should be disposed within a limited space, a gap distance between the plurality of signal lines DL, VDDL, VSSL and REFL and the plurality of circuit elements CE1, CE2, CE3 and CE4 is formed to be short, and thus parasitic capacitance can be generated and affected therebetween.

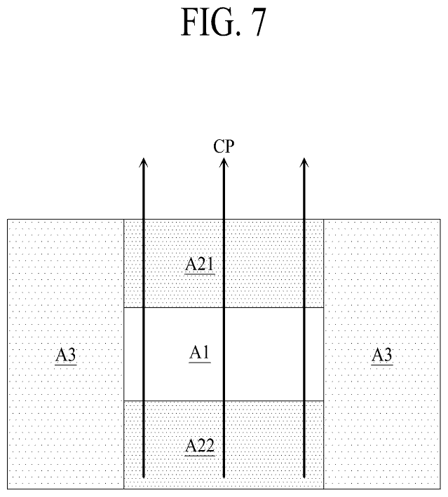

Also, the capacitors Cst1, Cst2, Cst3 and Cst4 included in each of the plurality of circuit elements CE1, CE2, CE3 and CE4 cannot have sufficient areas. As the areas of the capacitors Cst1, Cst2, Cst3 and Cst4 are reduced, the driving voltage Vgs charged in the capacitors Cst1, Cst2, Cst3 and Cst4 can be reduced, and thus luminance can be reduced. As shown in FIG. 7, when a partial area A1 emits light with bright luminance, a crosstalk phenomenon can occur in which an upper area A21 and a lower area A22, which are disposed on a driving current path CP passing through the partial area A1, appear to be darker than a peripheral area A3.

In the transparent display panel 110 according to one exemplary embodiment of the present disclosure, at least one of the plurality of circuit elements CE1, CE2, CE3 and CE4 can be disposed in the second non-transmissive area NTA2 to make sure of the area of the capacitors Cst1, Cst2, Cst3 and Cst4. For example, in the transparent display panel 110 according to one exemplary embodiment of the present disclosure, the fourth circuit element CE4 for the fourth subpixel SP4 can be disposed in the second non-transmissive area NTA2. In addition, the first to third circuit elements CE1, CE2 and CE3 for the first to third subpixels SP1, SP2 and SP3 can be disposed in the first non-transmissive area NTA1.

In the transparent display panel 110 according to one exemplary embodiment of the present disclosure, the fourth circuit element CE4 can be disposed in the second non-transmissive area NTA2, so that the areas of the capacitors Cst1, Cst2 and Cst3 of the first to third circuit elements CE1, CE2 and CE3 disposed in the first non-transmissive area NTA1 can be increased. Therefore, the transparent display panel 110 according to one exemplary embodiment of the present disclosure can reduce or prevent luminance of the first to third subpixels SP1, SP2 and SP3 from being reduced.

Also, in the transparent display panel 110 according to one exemplary embodiment of the present disclosure, the fourth capacitor Cst4 of the fourth circuit element CE4 disposed in the second non-transmissive area NTA2 can have a sufficient area. As an example, the fourth capacitor Cst4 of the fourth circuit element CE4 can have a larger formation area than the first to third capacitors Cst1, Cst2 and Cst3 of the first to third circuit elements CE1, CE2 and CE3. Embodiments are not limited thereto. As an example, the fourth capacitor Cst4 of the fourth circuit clement CE4 can have a formation area equal to or smaller than the first to third capacitors Cst1, Cst2 and Cst3 of the first to third circuit elements CE1, CE2 and CE3.

The fourth subpixel SP4 connected to the fourth circuit element CE4 can be a white subpixel. Since the white subpixel is used to implement brightness, a decrease in luminance due to a decrease in the area of the capacitor can be greater than that of the subpixel of another color, and can greatly affect a crosstalk phenomenon. In the transparent display panel 110 according to one exemplary embodiment of the present disclosure, the white subpixel can be disposed in the second non-transmissive area NTA2, and the fourth circuit clement CE4 connected to the white subpixel can be also disposed in the second non-transmissive area NTA2 having a relatively spare space. Therefore, the transparent display panel 110 according to one exemplary embodiment of the present disclosure can sufficiently make sure of the area of the fourth capacitor Cst4 included in the fourth circuit element CE4, thereby reducing or preventing luminance of the white subpixel from being reduced. Furthermore, the transparent display panel 110 according to one exemplary embodiment of the present disclosure can improve a crosstalk defect.

The transparent display panel 110 according to one exemplary embodiment of the present disclosure can reduce manufacturing process costs, shorten the manufacturing process time, and further can reduce production energy as a product defect rate is reduced. Furthermore, the transparent display panel 110 according to one exemplary embodiment of the present disclosure can reduce occurrence of greenhouse gases that can occur due to the manufacturing process, thereby implementing environment/social/governance (ESG).

Also, in the transparent display panel 110 according to one exemplary embodiment of the present disclosure, the black matrix cannot be provided between the white subpixel disposed in the second non-transmissive area NTA2 and the transmissive area TA. Therefore, the transparent display panel 110 according to one exemplary embodiment of the present disclosure can reduce or minimize a width of the second non-transmissive area NTA2 in the second direction (e.g., Y-axis direction).

The transparent display panel 110 according to one exemplary embodiment of the present disclosure has an arrangement structure of the circuit elements CE1, CE2, CE3 and CE4 capable of reducing the sizes of the first non-transmissive area NTA1 and the second non-transmissive area NTA2, so that the size of the transmissive area TA can be increased, whereby light transmittance can be improved.

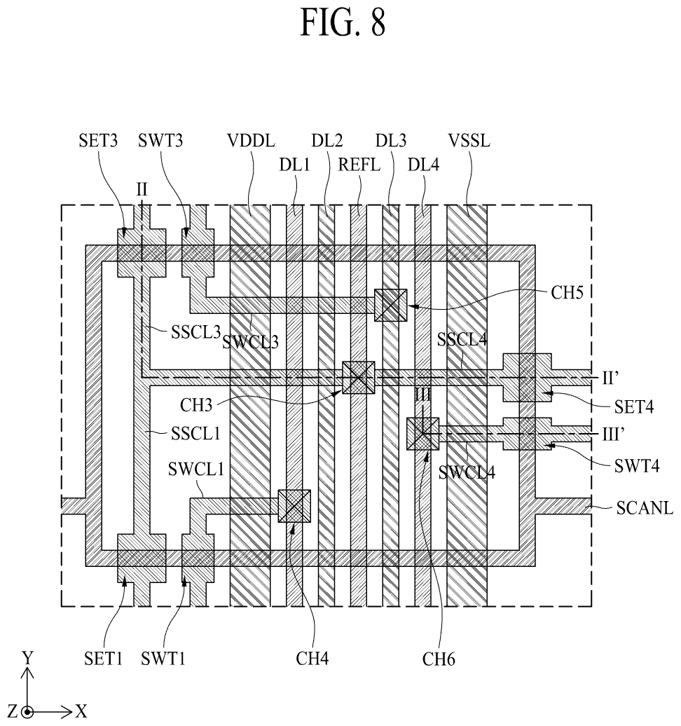

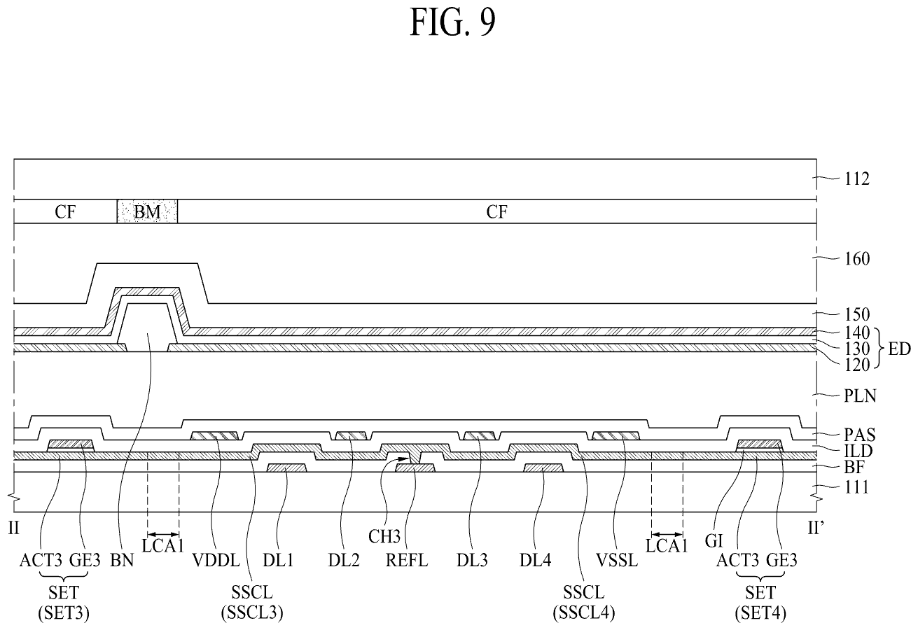

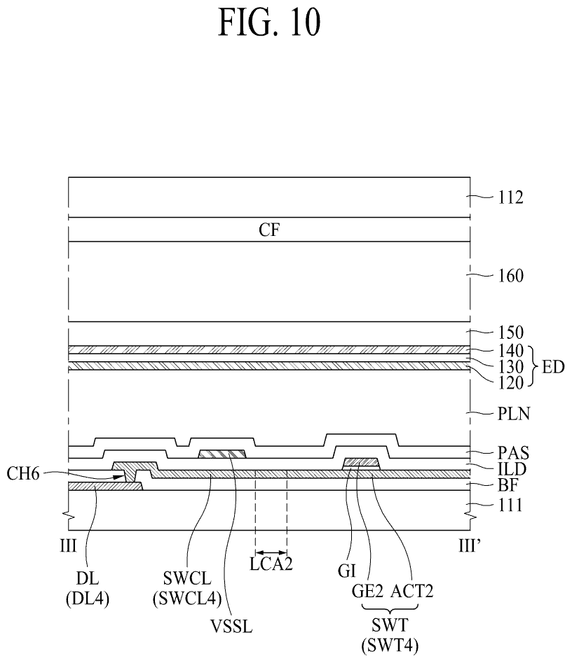

FIG. 8 is a view illustrating an example of a switching connection line and a sensing connection line, FIG. 9 is a cross-sectional view illustrating an example of an area along line II-II′ of FIG. 8, and FIG. 10 is a cross-sectional view illustrating an example of an area along line III-III′ of FIG. 8.

In the transparent display panel 110 according to the present disclosure, the capacitors Cst1, Cst2, Cst3 and Cst4 can be disposed between the switching transistors SWT1, SWT2, SWT3 and SWT4 and the driving transistors DT1, DT2, DT3 and DT4 in order to make sure of a maximum area of the capacitors Cst1, Cst2, Cst3 and Cst4 of the plurality of circuit elements CE1, CE2, CE3 and CE4.

Referring to FIG. 5, in the first circuit element CE1, the first capacitor Cst1 can be provided between the first switching transistor SWT1 and the first driving transistor DT1, so that the first driving transistor DT1, the first capacitor Cst1 and the first switching transistor SWT1 can be sequentially disposed in a row in the second direction (e.g., Y-axis direction). In the second circuit element CE2, the second capacitor Cst2 can be provided between the second switching transistor SWT2 and the second driving transistor DT2, so that the second switching transistor SWT2, the second capacitor Cst2 and the second driving transistor DT2 can be sequentially disposed in a row in the second direction (e.g., Y-axis direction). In the third circuit element CE3, the third capacitor Cst3 can be provided between the third switching transistor SWT3 and the third driving transistor DT3, so that the third switching transistor SWT3, the third capacitor Cst3 and the third driving transistor DT3 can be sequentially disposed in a row in the second direction (e.g., Y-axis direction).

The circuit elements CE1, CE2 and CE3 included in the first circuit portion C1 can include two circuit elements spaced apart from each other with the scan line SCANL interposed therebetween. As an example, the circuit elements CE1, CE2 and CE3 included in the first circuit portion C1 can include two circuit elements symmetrical with each other with respect to the scan line SCANL interposed therebetween, without being limited thereto. For example, the first circuit element CE1 and the third circuit element CE3, which are included in the first circuit portion C1, can be disposed to be symmetrical with respect to the scan line SCANL. As an example, the arrangement order of the switching transistor, the capacitor and the driving transistor, which are included in each of the first circuit elements CE1 and CE3, can be symmetrical with each other with respect to the scan line SCANL. The first circuit element CE1 can be disposed on one side of the scan line SCANL (e.g., a first scan line), and can be disposed in the order of the first switching transistor SWT1, the first capacitor Cst1 and the first driving transistor DT1 based on the scan line SCANL. In detail, in the first circuit element CE1, the first switching transistor SWT1, the first capacitor Cst1 and the first driving transistor DT1 can be sequentially disposed based on the scan line SCANL. The third circuit element CE3 can be disposed on the other side of the scan line SCANL (e.g., a second scan line adjacent to the first scan line), and can be disposed in the order of the third switching transistor SWT3, the third capacitor Cst3, and the third driving transistor DT3 based on the scan line SCANL. In detail, in the third circuit element CE3, the third switching transistor SWT3, the third capacitor Cst3, and the third driving transistor DT3 can be sequentially disposed based on the scan line SCANL. In addition, in the second circuit element CE2, the second switching transistor SWT2, the second capacitor Cst2 and the second driving transistor DT2 can be sequentially disposed based on the scan line SCANL (e.g., the second scan line).

Meanwhile, the first circuit element CE1 and the third circuit element CE3 can further include a first sensing transistor SET1 and a third sensing transistor SET3, respectively. As shown in FIG. 8, the first sensing transistor SET1 can be disposed to be adjacent to the first switching transistor SWT1. As an example, the first sensing transistor SET1 and the first switching transistor SWT1 can partially overlap the scan line SCANL on one side of the scan line SCANL, and can be disposed to be spaced apart from each other at a predetermined interval along one side of the scan line SCANL. The third sensing transistor SET3 and the third switching transistor SWT3 can partially overlap the scan line SCANL on the other side of the scan line SCANL, and can be disposed to be spaced apart from each other at a predetermined interval along the other side of the scan line SCANL. The first sensing transistor SET1 of the first circuit element CE1 can be disposed to face the third sensing transistor SET3 of the third circuit element CE3, and the first switching transistor SWT1 of the first circuit element CE1 can be disposed to face the third switching transistor SWT3 of the third circuit element CE3.

The fourth circuit clement CE4 can include a fourth capacitor Cst4 between the fourth switching transistor SWT4 and the fourth driving transistor DT4. In this case, the fourth switching transistor SWT4 can be disposed to be closer to the fourth data line DL4 than the fourth driving transistor DT4 in order to receive a data voltage from the fourth data line DLA, without being limited thereto.

Meanwhile, the fourth circuit element CE4 can further include a fourth sensing transistor SET4. As shown in FIG. 8, the fourth sensing transistor SET4 can be disposed to be adjacent to the fourth switching transistor SWT4. The fourth sensing transistor SET4 and the fourth switching transistor SWT4 can partially overlap the scan line SCANL, and can be spaced apart from each other at a predetermined interval along the scan line SCANL. The fourth sensing transistor SET4 can be disposed to be closer to the reference line REFL than the fourth driving transistor DT4 in order to receive a reference voltage from the reference line REFL, without being limited thereto.

A gap distance of the fourth driving transistor DT4 from a first signal line group that includes a fourth data line DLA connected to the fourth switching transistor SWT4 and a reference line REFL connected to the fourth sensing transistor SET4 can be increased. Therefore, as an example, the fourth driving transistor DT4 can be connected to the pixel power line VDDL that is included in a first signal line group different from the first signal line group that includes the fourth data line DL4 connected to the fourth switching transistor SWT4 and the reference line REFL connected to the fourth sensing transistor SET4. As an example, the pixel power line VDDL can be disposed leftmost in the first signal line group, without being limited thereto. As an example, the pixel power line VDDL in one first signal line group can be farther away from the fourth driving transistor DT4 than the fourth data line DLA and the reference line REFL in the one first signal line group, without being limited thereto. Embodiments are not limited thereto. As an example, the fourth driving transistor DT4 can be connected to the pixel power line VDDL that is included in a first signal line group the same as the first signal line group that includes the fourth data line DL4 connected to the fourth switching transistor SWT4 and the reference line REFL connected to the fourth sensing transistor SET4.

In this case, as an example, the first signal line group that includes the fourth data line DL4 connected to the fourth switching transistor SWT4 and the reference line REFL connected to the fourth sensing transistor SET4 can be disposed in an area that overlaps the corresponding fourth subpixel SP4. On the other hand, the different first signal line group can be disposed in an area that overlaps the fourth subpixel SP4 disposed to be adjacent to the corresponding fourth subpixel SP4 in the first direction (e.g., X-axis direction). The pixel power line VDDL of the different first signal line group can be spaced apart from the fourth data line DLA connected to the fourth switching transistor SWT4 and the reference line REFL connected to the fourth sensing transistor SET4 with the transmissive area TA interposed therebetween.

The fourth switching transistor SWT4, the fourth sensing transistor SET4, the fourth capacitor Cst4 and the fourth driving transistor DT4 can be disposed between a first signal line group disposed in an area that overlaps the corresponding fourth subpixel SP4 and a first signal line group disposed in an area that overlaps the fourth subpixel SP4 disposed to adjacent to the corresponding subpixel SP4 in the first direction (e.g., X-axis direction). The fourth switching transistor SWT4 and the fourth sensing transistor SET4 can be disposed to be closer to the fourth data line DL and the reference line REFL of the first signal line group disposed in the area that overlaps the corresponding fourth subpixel SP4 than the fourth driving transistor DT4. Meanwhile, the fourth driving transistor DT4 can be disposed to be closer to the pixel power line VDDL of the first signal line group, which is disposed in the area that overlaps the fourth subpixel SP4 disposed to be adjacent to the corresponding fourth subpixel SP4 in the first direction (e.g., X-axis direction), than the fourth switching transistor SWT4 and the fourth sensing transistor SET4.

As a result, the fourth circuit element CE4 can be disposed in the first direction (e.g., X-axis direction) in the order of the fourth switching transistor SWT4, the fourth capacitor Cst4 and the fourth driving transistor DT4, or in the order of the fourth sensing transistor SET4, the fourth capacitor Cst4 and the fourth driving transistor DT4. In detail, as an example, in the fourth circuit element CE4, the fourth switching transistor SWT4, the fourth capacitor Cst4 and the fourth driving transistor DT4 can be sequentially disposed, or the fourth sensing transistor SET4, the fourth capacitor Cst4 and the fourth driving transistor DT4 can be sequentially disposed.

The switching transistors SWT1, SWT2, SWT3 and SWT4 and the sensing transistors SET1, SET2, SET3 and SET4, which are respectively included in the circuit elements CE1, CE2, CE3 and CE4, can be connected to the signal lines DL1, DL2, DL3, DL4 and REFL provided in the first non-transmissive area NTA1. The switching transistors SWT1, SWT2, SWT3 and SWT4 can receive a data voltage from the data lines DL1, DL2, DL3 and DL4 extended in the second direction (e.g., Y-axis direction) in the first non-transmissive area NTA1. To this end, the switching transistors SWT1, SWT2, SWT3 and SWT4 can be electrically connected to the data lines DL1, DL2, DL3 and DLA through a switching connection line SWCL.

Referring to FIG. 8, the first switching transistor SWT1 included in the first circuit clement CE1 can be connected to the first data line DL1 through a first switching connection line SWCL1. The first switching connection line SWCL1 can be connected to the first data line DL1 at one end through a fourth contact hole CH4, and can be connected to the active layer ACT2 of the first switching transistor SWT1 at the other end.

The third switching transistor SWT3 included in the third circuit element CE3 can be connected to the third data line DL3 through a third switching connection line SWCL3. The third switching connection line SWCL3 can be connected to the third data line DL3 at one end through a fifth contact hole CH5, and can be connected to the active layer ACT2 of the third switching transistor SWT3 at the other end.

The fourth switching transistor SWT4 included in the fourth circuit element CE4 can be connected to the fourth data line DLA through a fourth switching connection line SWCL4. As shown in FIG. 10, the fourth switching connection line SWCL4 can be connected to the fourth data line DL4 at one end through a sixth contact hole CH6, and can be connected to the active layer ACT2 of the fourth switching transistor SWT4 at the other end.

Although not shown in FIG. 8, the second switching transistor SWT2 included in the second circuit element CE2 can be also connected to the second data line DL2 through a second switching connection line (not shown). The second switching connection line (not shown) can be connected to the second data line DL2 at one end through a contact hole, and can be connected to the active layer ACT2 of the second switching transistor SWT2 at the other end.

In addition, the sensing transistors SET1, SET2, SET3 and SET4 can receive a reference voltage (or an initialization voltage) from the reference line REFL extended in the second direction (e.g., Y-axis direction) in the first non-transmissive area NTA1. To this end, the sensing transistors SET1, SET2, SET3 and SET4 can be electrically connected to the reference line REFL through a sensing connection line SSCL.

Referring to FIG. 8, the first sensing transistor SET1 included in the first circuit element CE1 can be connected to the reference line REFL through a first sensing connection line SSCL1. The first sensing connection line SSCL1 can be connected to the reference line REFL through a third contact hole CH3, and can be connected to the active layer ACT3 of the first sensing transistor SST1 at one end.

The third sensing transistor SET3 included in the third circuit element CE3 can be connected to the reference line REFL through a third sensing connection line SSCL3. As shown in FIG. 9, the third sensing connection line SSCL3 can be connected to the reference line REFL through the third contact hole CH3, and can be connected to the active layer ACT3 of the third sensing transistor SET3 at one end.

The fourth sensing transistor SET4 included in the fourth circuit element CE4 can be connected to the reference line REFL through a fourth sensing connection line SSCL4. As shown in FIG. 9, the fourth sensing connection line SSCL4 can be connected to the reference line REFL through the third contact hole CH3, and can be connected to the active layer ACT3 of the fourth sensing transistor SST4 at one end.

Although not shown in FIG. 8, a second sensing transistor (not shown) included in the second circuit element CE2 can be also connected to the reference line REFL through the second sensing connection line (not shown). The second sensing connection line (not shown) can be connected to the reference line REFL at one end through a contact hole, and can be connected to an active layer of the second sensing transistor (not shown) at the other end.

In the transparent display panel 110 according to one exemplary embodiment of the present disclosure, as an example, the switching connection line SWCL and the sensing connection line SSCL can be disposed on the same layer, or can be disposed on different layers. In the transparent display panel 110 according to one exemplary embodiment of the present disclosure, each of the switching connection line SWCL and the sensing connection line SSCL can be formed of a silicon-based semiconductor material or an oxide-based semiconductor material. or any other semiconductor materials or conductive materials. For example, each of the switching connection line SWCL and the sensing connection line SSCL can be formed of the same material on the same layer as the active layer ACT1 of the driving transistor DT, without being limited thereto.

The transparent display panel 110 according to one exemplary embodiment of the present disclosure can include a second laser cutting area LCA2 in the switching connection line SWCL as shown in FIG. 10. In the transparent display panel 110 according to one exemplary embodiment of the present disclosure, when a defect occurs in the switching transistor SWT (e.g., the fourth switching transistor SWT4), a second laser cutting area LCA2 of the switching connection line SWCL (e.g., the fourth switching connection line SWCL4) connected to the switching transistor SWT (e.g., the fourth switching transistor SWT4) in which the defect has occurred can be cut using a laser.

Also, the transparent display panel 110 according to one exemplary embodiment of the present disclosure can include a first laser cutting area LCA1 in the sensing connection line SSCL as shown in FIG. 9. In the transparent display panel 110 according to one exemplary embodiment of the present disclosure, when a defect occurs in the sensing transistor SET (e.g., the fourth sensing transistor SET4), the first laser cutting area LCA1 of the sensing connection line SSCL (e.g., the fourth sensing connection line SSCL4) connected to the sensing transistor SET (e.g., the fourth sensing transistor SET4) in which the defect has occurred can be cut using a laser.

In the transparent display panel 110 according to one exemplary embodiment of the present disclosure, as an example, each of the switching connection line SWCL and the sensing connection line SSCL can be made of a silicon-based semiconductor material or an oxide-based semiconductor material. The silicon-based semiconductor material or the oxide-based semiconductor material can be more thermally condensed than a metal material such as Cu during laser irradiation, thereby generating high heat. Therefore, the silicon-based semiconductor material or the oxide-based semiconductor material can be more easily broken than other metal materials. That is, as an example, in the transparent display panel 110 according to one exemplary embodiment of the present disclosure, each of the switching connection line SWCL and the sensing connection line SSCL can be made of a silicon-based semiconductor material or an oxide-based semiconductor material, thereby certainly making sure of electrical separation from the defective switching transistor SWT or the defective sensing transistor SET during laser cutting. Embodiments are not limited thereto. As an example, at least one of the first laser cutting area LCA1 and the second laser cutting area LCA2 can be omitted depending on the design.

Also, in the transparent display panel 110 according to one exemplary embodiment of the present disclosure, the switching connection line SWCL and the sensing connection line SSCL, which are provided on the same layer as the active layer ACT1 of the driving transistor DT, can be laser cut so that the light emitting element ED provided at an upper portion can be repaired without damage.

Meanwhile, in the transparent display panel 110 according to one exemplary embodiment of the present disclosure, the plurality of sensing connection lines SSCL respectively connected to the plurality of sensing transistors SET can be connected to the reference line REFL through one contact hole CH3. In the transparent display panel 110 according to one exemplary embodiment of the present disclosure, the first and third sensing connection lines SSCL1 and SSCL3 connected to the first and third sensing transistor SET1 and SET3 of the first circuit portion C1 and the fourth sensing connection line SSCL4 connected to the fourth sensing transistor SET4 of the second circuit portion C2 can be connected to each other on the same layer. In addition, the first and third sensing connection lines SSCL1 and SSCL3 connected to the first and third sensing transistors SET1 and SET3 of the first circuit portion C1 and the fourth sensing transistor SET4 of the second circuit portion C2 can be connected to the reference line REFL through one third contact hole CH3.

As a result, in the transparent display panel 110 according to one exemplary embodiment of the present disclosure, the number of contact holes can be reduced. Therefore, an area increased as the contact holes are formed can be reduced or minimized, and further the size of the non-transmissive area NTA can be reduced or minimized.

According to the present disclosure, the following advantageous effects can be obtained.

In the present disclosure, the circuit elements of the first circuit portion can be disposed to be collected on one side of the first signal line in the first non-transmissive area, so that the space for separating the circuit elements from the plurality of signal lines can be reduced or minimized. Therefore, the size of the area in which the plurality of signal lines included in the first signal line and the circuit elements included in the first circuit portion are formed can be reduced or minimized.

Also, at least one (e.g., one, two, three or more) of the plurality of circuit elements can be disposed in the second non-transmissive area, so that the area of the capacitor included in each of the plurality of circuit elements can be increased. Therefore, a decrease in luminance of the subpixel can be reduced, and a crosstalk defect can be resolved.

Also, in the present disclosure, the product defect rate can be reduced, so that the manufacturing process cost can be reduced and the manufacturing process time can be shortened, and further production energy can be reduced. In addition, the present disclosure can reduce occurrence of greenhouse gases that can occur due to the manufacturing process, thereby implementing environment/social/governance (ESG).

Also, in the present disclosure, each of the switching connection line and the sensing connection line can be made of a silicon-based semiconductor material or an oxide-based semiconductor material, thereby certainly making sure of electrical separation from the defective switching transistor or the defective sensing transistor during laser cutting.

Also, in the present disclosure, the switching connection line and the sensing connection line are provided on the same layer as the active layer of the driving transistor, so that the light emitting element provided at an upper portion can be repaired without damage during laser cutting.

Also, in the present disclosure, the plurality of sensing connection lines respectively connected to the plurality of sensing transistors are connected to the reference line through a single contact hole, so that the number of contact holes can be reduced. Therefore, an area increased as the contact holes are formed can be reduced or minimized, and further the size of the non-transmissive area NTA can be reduced or minimized.

It will be apparent to those skilled in the art that the present disclosure described above is not limited by the above-described embodiments and the accompanying drawings and that various substitutions, modifications and variations can be made in the present disclosure without departing from the spirit or scope of the disclosures.

What is claimed is:

1. A transparent display device comprising:
a display area in which a plurality of subpixels are disposed to display an image;
a plurality of transmissive areas disposed within the display area, transmitting external light;
a first non-transmissive area disposed between the transmissive areas disposed to be adjacent to each other in a first direction, not transmitting external light;
a second non-transmissive area disposed between the transmissive areas disposed to be adjacent to each other in a second direction, not transmitting external light;
a first circuit portion disposed in the first non-transmissive area to drive the subpixels; and
a second circuit portion disposed in the second non-transmissive area to drive the subpixels.

2. The transparent display device of claim 1, further comprising a first signal line extended in the second direction in the first non-transmissive area,
wherein an area in which the first signal line is provided is disposed between the first circuit portion and the transmissive area.

3. The transparent display device of claim 2, wherein the first circuit portion is formed along an edge area in one side of the first non-transmissive area.

4. The transparent display device of claim 2, wherein the first signal line includes:
a first data line for supplying a data voltage to the subpixel disposed in the first non-transmissive area,
a second data line for supplying a data voltage to the subpixel disposed in the second non-transmissive area, and
a reference line for supplying a reference voltage to the subpixel disposed in the first non-transmissive area and the subpixel disposed in the second non-transmissive area.

5. The transparent display device of claim 2, wherein the first circuit portion and the second circuit portion are disposed on opposite sides of the area in which the first signal line is provided.

6. The transparent display device of claim 5, wherein the area in which the first signal line is provided is disposed between the first circuit portion and the transmissive area adjacent to the second circuit portion in the second direction.

7. The transparent display device of claim 2, wherein each of the first signal line includes:
a first data line for supplying a data voltage to the subpixel disposed in the first non-transmissive area,
a second data line for supplying a data voltage to the subpixel disposed in the second non-transmissive area on one side of the first non-transmissive area, and
a power line for supplying a power source to the subpixel disposed in the second non-transmissive area on the other side opposite to the one side of the first non-transmissive area.

8. The transparent display device of claim 7, wherein the first data line and the second data line are closer to the subpixel disposed in the second non-transmissive area on the one side of the first non-transmissive area than the power line.

9. The transparent display device of claim 1, wherein the first circuit portion is configured to drive the subpixels disposed in the first non-transmissive area, and the second circuit portion is configured to drive the subpixels disposed in the second non-transmissive area.

10. The transparent display device of claim 1, further comprising a second signal line extended in the first direction in the second non-transmissive area,
wherein the second signal line includes a scan line for supplying a scan signal to the subpixel disposed in the first non-transmissive area and the subpixel disposed in the second non-transmissive area.

11. The transparent display device of claim 2, further comprising a second signal line extended in the first direction in the second non-transmissive area,
wherein the second signal line includes a scan line for supplying a scan signal to the subpixel disposed in the first non-transmissive area and the subpixel disposed in the second non-transmissive area,
wherein the first signal line and the first circuit portion are disposed not to overlap each other, and
the second signal line and the second circuit portion are disposed not to overlap each other.

12. The transparent display device of claim 1, wherein a plurality of subpixels are disposed in the first non-transmissive area, and
the first circuit portion includes a plurality of circuit elements for the plurality of subpixels disposed in the first non-transmissive area.

13. The transparent display device of claim 12, wherein the plurality of circuit elements of the first circuit portion are disposed in a row in the second direction.

14. The transparent display device of claim 1, wherein one subpixel is disposed in the second non-transmissive area,
the second circuit portion includes one circuit element for the one subpixel disposed in the second non-transmissive area.

15. The transparent display device of claim 14, wherein the one circuit element includes a capacitor and at least one transistor.

16. The transparent display device of claim 15, wherein the at least one transistor includes a driving transistor for supplying a driving current to the one subpixel and a switching transistor for supplying a data voltage supplied from a data line to the driving transistor, and
the capacitor is disposed between the driving transistor and the switching transistor.

17. The transparent display device of claim 16, wherein the switching transistor is disposed to be closer to the data line than the driving transistor.

18. The transparent display device of claim 1, further comprising:
a data line extended in the second direction in the first non-transmissive area, supplying a data voltage to the subpixel disposed in the second non-transmissive area; and
a reference line extended in the second direction in the first non-transmissive area, supplying a reference voltage to the subpixel disposed in the second non-transmissive area,
wherein the second circuit portion includes a switching transistor connected to the data line and a sensing transistor connected to the reference line.

19. The transparent display device of claim 18, further comprising:
a switching connection line connecting the data line with the switching transistor; and
a sensing connection line connecting the reference line with the sensing transistor,
wherein the switching connection line and the sensing connection line are disposed on the same layer.

20. The transparent display device of claim 18, further comprising a power line disposed to be spaced apart from the data line and the reference line with one transmissive area interposed therebetween and extended in the second direction,
wherein the power line is configured to supply a power source to the subpixel disposed in the second non-transmissive area,
wherein the second circuit portion further includes a driving transistor connected to the power line.

21. The transparent display device of claim 20, wherein the sensing transistor is disposed to be closer to the reference line than the driving transistor, and the driving transistor is disposed to be closer to the power line than the sensing transistor.

22. The transparent display device of claim 20, wherein the driving transistor includes an active layer, a drain electrode, a source electrode, and a gate electrode, and
the switching connection line and the sensing connection line are formed of the same material on the same layer as the active layer of the driving transistor.

23. The transparent display device of claim 19, wherein each of the switching connection line and the sensing connection line is made of a silicon-based semiconductor material or an oxide-based semiconductor material.

24. The transparent display device of claim 1, further comprising a scan line extended in the first direction in the second non-transmissive area,
wherein the first circuit portion includes two circuit elements disposed to be symmetrical with each other based on the scan line.

25. The transparent display device of claim 24, wherein the first circuit portion includes a first circuit element disposed on one side of the scan line and a second circuit element disposed on an opposite side of one side of the scan line,
each of the first circuit element and the second circuit element includes a switching transistor, a capacitor, and a driving transistor, and
in each of the first circuit element and the second circuit element, the switching transistor, the capacitor, and the driving transistor are sequentially disposed based on the scan line.

26. The transparent display device of claim 1, further comprising:
a reference line for supplying a reference voltage to a sensing transistor of the first circuit portion disposed in the first non-transmissive area and a sensing transistor of the second circuit portion disposed in the second non-transmissive area;
a first sensing connection line connecting the reference line to the sensing transistor of the first circuit portion; and
a second sensing connection line connecting the reference line and the sensing transistor of the second circuit portion,
wherein the first sensing connection line and the second sensing connection line are connected to each other on the same layer.

27. The transparent display device of claim 26, wherein the first sensing connection line and the second sensing connection line are connected to the reference line through the same contact hole.

28. The transparent display device of claim 1, wherein each of the first circuit portion and the second circuit portion includes a capacitor, and
the capacitor of the second circuit portion has a larger formation area than the capacitor of the first circuit portion.

29. The transparent display device of claim 1, wherein the subpixels disposed in the second non-transmissive area are white subpixels.
